(19) United States
(12) Patent Application Publication
(10) Pub. No.: US 2011/0317355 A1
(43) Pub. Date: Dec. 29, 2011

(54) Memory Device Having Wireless Recognition Function and a Portable Electronic Apparatus Integrating the Same

(76) Inventor: En-Min Jow, Hsinchu (TW)

(21) Appl. No.: 12/970,440

(22) Filed: Dec. 16, 2010

(30) Foreign Application Priority Data
Jun. 28, 2010 (TW) 099121015

(51) Int. Cl. H05K 7/00; G06K 19/077

(52) U.S. Cl. 361/679.31; 235/492

(57) ABSTRACT

A memory device having wireless recognition function provided inside a portable electronic apparatus includes a semiconductor package having a substrate, a semiconductor chip disposed on the substrate, an antenna disposed on the substrate and electrically connected to the semiconductor chip, and an encapsulant encapsulating the semiconductor chip; and a magnetic member coupled to the encapsulant and spaced apart from the substrate by a pre-determined distance, in a manner that a projection area of the magnetic member on the substrate covers an area disposed with the antenna, thereby guiding electromagnetic waves emitted from the antenna in specific directions so as to enhance magnetic forces in the specific directions and enable the magnetic forces to penetrate a thicker casing in order to achieve a sensing chip having a sensing function, hence a mobile phone has an access card function.

### BACKGROUND OF THE INVENTION

1. Field of the Invention

This invention relates to memory devices, and more particularly, to a memory device having a wireless recognition function.

2. Description of Related Art

Electronic products tend to be multi-functional in order to achieve human needs, for instance, 3G mobile phones. Hence, sensing function is integrated in an electronic product, for instance, a mobile phone, so as to enable the mobile phone to have function of electronic wallet and access card.

Referring to FIGS. 1A, 1B, and 2, FIG. 1A shows a conventional mobile phone 1, and FIG. 1B shows a conventional access card 2, for instance, an easy card. As illustrated in FIG. 2, the access card 2 has a substrate 200 on which a chip 20 having a wireless recognition function and an antenna 203 for sensing radio waves from a reader electrically connected to the chip 20, are mounted. An encapsulant 204 encapsulates the substrate 200, the chip 20, and the antenna 203. Since a casing 2a of the access card 2 is thin enough, electromagnetic waves from the antenna 203 can penetrate the casing 2a of the access card 2 when in operation of the chip 20, in order to respond to the reader. As such, the access card 2 is able to perform data access or personal identification.

However, since a thickness h of the casing la of the mobile phone a is much larger than a thickness d of the casing 2a of the access card 2, and since the antenna inside the chip having a wireless recognition function emits the electromagnetic waves in a divergence way, the electromagnetic waves of the chip having a wireless recognition function is hard to concentrate and then penetrate the casing 1a of the mobile phone 1, and magnetic flux penetrating the casing 1a of the mobile phone 1 is not enough, hence sensing work is ineffectively executed.

So a problem immediately to be solved is that how to overcome the existing technique and then achieve the portable electronic apparatus having effective sensing function.

### SUMMARY OF THE INVENTION

A memory device having wireless recognition function is provided according to the present invention. The memory device having wireless recognition function is provided inside a portable electronic apparatus. The memory device having wireless recognition function comprises a semiconductor package comprising a substrate, a semiconductor chip disposed on the substrate, at least an antenna disposed on the substrate and electrically connected to the semiconductor chip, and an encapsulant encapsulating the semiconductor chip; and a magnetic member coupled to the encapsulant and spaced apart from the substrate by a pre-determined distance, in a manner that a projection area of the magnetic member on the substrate covers an area disposed with the antenna. The semiconductor chip of the previously described memory device having wireless recognition function comprises a memory integrated circuit and a wireless recognition integrated circuit. Additionally, the semiconductor package further comprises a control chip electrically connected to the semiconductor chip, wherein the control chip may be embedded inside the encapsulant or may be disposed outside the encapsulant.

Specifically, the semiconductor package comprises a ground surface located on the substrate and an opposing active surface, and the magnetic member is disposed on the active surface side. In another embodiment, the magnetic member is disposed on the semiconductor package. Particularly, since the semiconductor package comprises a ground surface located on the substrate and an opposing active surface, the magnetic member is disposed on the active surface side of the semiconductor package.

Moreover, the antenna may be disposed outside the encapsulant, or, the encapsulant further encapsulates the antenna.

In another aspect, the present invention further discloses a portable electronic apparatus comprising a casing, a circuit board disposed inside the casing, and the memory device having wireless recognition function of this invention disposed on the circuit board, wherein the semiconductor package comprises the antenna, and the magnetic member guide electromagnetic waves emitted from the antenna in specific directions.

The memory device having wireless recognition function and the portable electronic apparatus having the memory device enable the electromagnetic waves in the specific directions to penetrate a thicker casing via enhancing magnetic energy of the antenna in the specific directions by the magnetic member, such that sufficient magnetic flux enabling a sensing chip to have sensing function results in the portable electronic apparatus having functions of accessing card, electronic wallet, etc..

### BRIEF DESCRIPTION OF DRAWINGS

The invention can be more fully understood by reading the following detailed description of the preferred embodiments, with reference made to the accompanying drawings, wherein:

FIG. 1A is a stereoscopic schematic drawing of a mobile phone according to the prior art;

FIG. 1B is a stereoscopic schematic drawing of a access card according to the prior art;

FIG. 2 is a cross-sectional schematic view of the access card according to the prior art;

FIGS. 3A, 3B, and 3C are respectively a cross-sectional schematic view of a memory device having a wireless recognition function in accordance with the present invention;

FIGS. 4A and 4B are respectively a top view of the memory device having wireless recognition function in accordance with the present invention; and

FIG. 5 is a stereoscopic schematic drawing of a portable electronic apparatus in accordance with the present invention.

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification.

It has to be noted that the drawings of the present invention showing embodiments of structure, scale, dimension, etc. are corresponding to the disclosure of the specification so as to be understood and read by those in the art and are not to restrict embodiments, hence no technically substantial meanings. Any decoration of structure, change of scale relationship, or regulation of scale are within scope of disclosed technical content of the present invention under not effecting function and achievement of the present invention. At the same time, terms of the specification, such as “above”, “below”, “inside”, “outside”, “a”, and “side”, etc. are defined for clear description and not for restricting scope of the present invention. Change or regulation of corresponding relationship is within the scope of embodiment of the present invention under no substantially technical change.

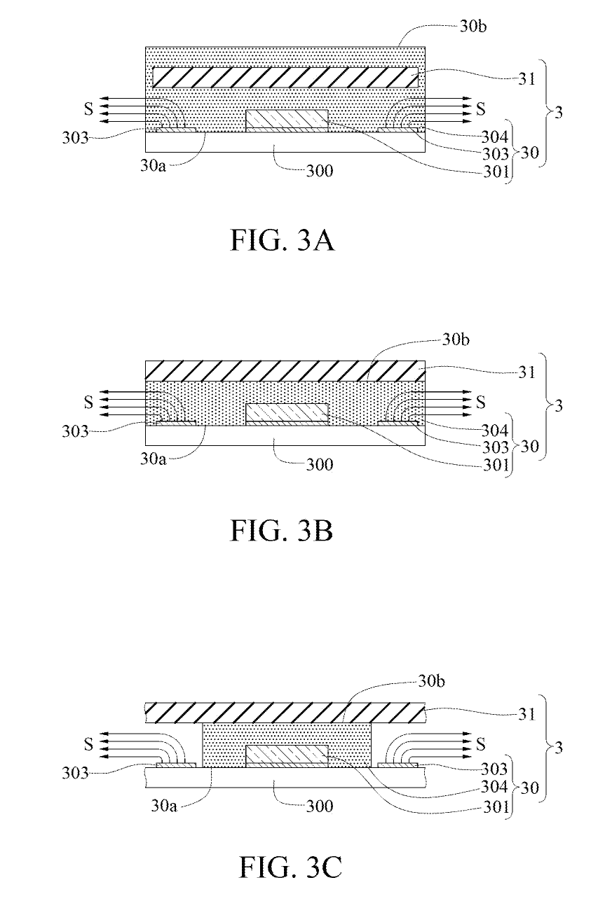

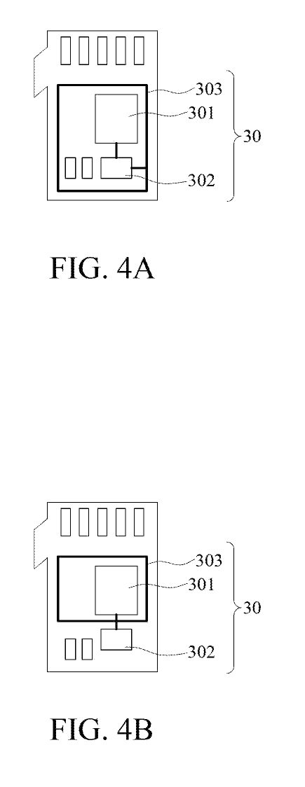

Referring to FIGS. 3A, 3B, and 4A, a memory device 3 having a wireless recognition function in accordance with the present invention are shown. The memory device 3 can be disposed inside a portable electronic apparatus, so as to enable the portable electronic apparatus to be provided with a sensing function, for instance, a mobile phone having easy card function. The memory device 3 comprises a semiconductor package 30 and a magnetic member 31.

The semiconductor package 30 has a substrate 300, a semiconductor chip 301, a control chip 302, and an antenna 303 electrically connected to the semiconductor chip 301 and the control chip 302. The semiconductor chip 301, the control chip 302 and the antenna 303 are disposed on the substrate 300. The semiconductor package 30 further comprises an encapsulant 304 for encapsulating the semiconductor chip 301. The antenna 303 is in a shape of a coil and is provided on the substrate 300 and electrically connected to the semiconductor chip 301 so as to generate magnetism from electricity.

The magnetic member 31 is provided on one side of the semiconductor package 30 corresponding to the substrate 300 and the antenna 303 so as to position the encapsulant 304 between the magnetic member 31 and the antenna 303 and to enable a projection area of the magnetic member 31 on the substrate 300 to cover an area enclosed by the antenna 303. Moreover, the magnetic member 31 is a Ferrite which is a kind of economical and endurable hard sintering product. The Ferrite may be manufactured from metal powder, for instance, Fe₂O₃, BaCo₃, or SrCo₃, etc.. Furthermore, the Ferrite may be classified into Isotropic Magnet and Anisotropic Magnet, and the Anisotropic Magnet is classified into dry type and wet type.

In operation, the magnetic member 31 is used for guiding electromagnetic waves emitted from the antenna 303 to concentrate in specific directions, so as to enhance magnetic energy of the antenna 303 in the specific directions and to increase magnetic flux S in the specific directions, thereby enabling the semiconductor chip 301 to receive and emit signals easily.

As illustrated in FIG. 3A, the semiconductor package 30 has a ground surface 30a facing toward the substrate 300 and an active surface 30b opposing the ground surface 30a. Specifically, under consideration of the projection area of the magnetic member 31 on the substrate 300 covering the area enclosed by the antenna 303, the magnetic member 31 is embedded in the encapsulant 304.

In another embodiment, as illustrated in FIG. 3B, the magnetic member 31 is disposed on an external surface of the encapsulation package 30. Since the semiconductor package 30 has the ground surface 30a facing toward the substrate 300 and the active surface 30b opposing the ground surface 30a, particularly, in the embodiment, the magnetic member 31 is disposed on the active surface 30b of the semiconductor package 30 and is not encapsulated by the encapsulant 304. As illustrated in FIGS. 3A and 3B, the encapsulant 304 encapsulates the antenna 303. However, in another embodiment illustrated in FIG. 3C, the antenna 303 is provided outside the encapsulant 304 such that the encapsulant 304 only encapsulates the semiconductor chip 301. It should be noted that the projection area of the magnetic member 31 on the substrate 300 covers the area enclosed by the antenna 303 so as to increase the magnetic flux S.

In another aspect, the semiconductor chip 301 of the memory device 3 in accordance with the present invention comprises a memory integrated circuit and a wireless recognition integrated circuit, wherein the wireless recognition integrated circuit may be a Radio-frequency identification (RFID) circuit. The memory integrated circuit and the wireless recognition integrated circuit may be horizontally integrated on the substrate 300 by, for instance, providing respectively a memory chip and a wireless recognition chip on the substrate 300, or may be stacked with each other on the substrate 300 by a single semiconductor manufacturing process. Since the chip disposing method is not an essential feature of the present invention and is conventional in application, detailed description thereto is omitted in the specification and the drawings.

Since the control chip 302 is not used for sensing radio waves, the control chip 302 of the memory device 3 in accordance with the present invention can be, as illustrated in FIG. 4B, provided outside the antenna 303. However, It still has to be electrically connected to the semiconductor chip 301.

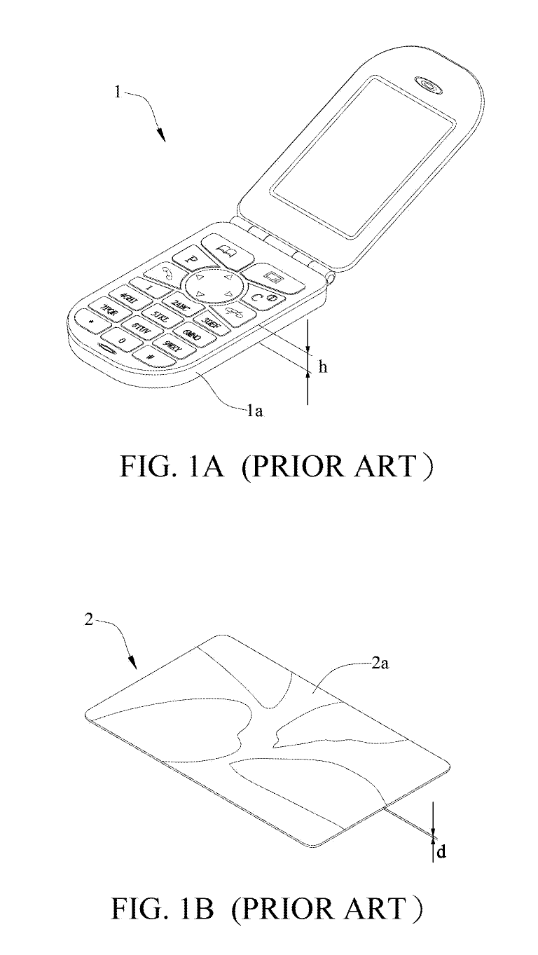

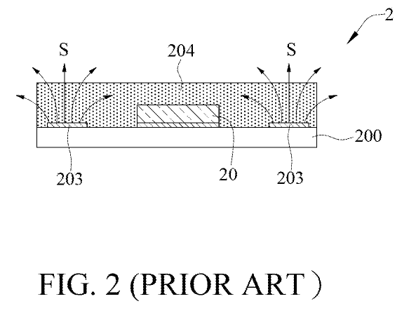

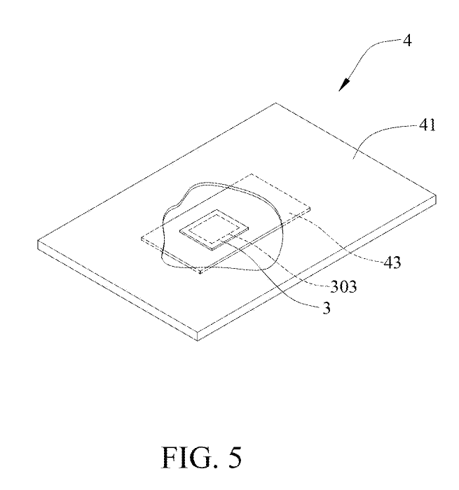

In another aspect illustrated in FIG. 5, the present invention further discloses a portable electronic apparatus 4 comprising a casing 41, a circuit board 43 provided inside the casing 41, and the memory device 3 disposed on the circuit board 43 in accordance with the present invention. The semiconductor package 30 has the antenna 303 for sensing the radio waves. The portable electronic apparatus 4 described previously may be an access card or a smart card, as illustrated in the drawings, or may be a PDA, a digital camera, a notebook, or the mobile phone 1 illustrated in FIG. 1A

In conclusion, the portable electronic apparatus and its chip memory card in accordance with the present invention enable the electromagnetic waves emitted from the antenna to be enhanced and to penetrate a thicker casing by providing the magnetic member on the semiconductor package, such that sufficient magnetic flux enabling a sensing chip to have a sensing function effectively results in the portable electronic apparatus having function of access card, electronic wallet, etc..

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A memory device having a wireless recognition function for being installed inside a portable electronic apparatus, comprising:
a semiconductor package comprising a substrate, a semiconductor chip disposed on the substrate, at least an antenna disposed on the substrate and electrically connected to the semiconductor chip, and an encapsulant encapsulating the semiconductor chip; and
a magnetic member coupled to the encapsulant and spaced apart from the substrate and the antenna by a pre-determined distance, in a manner that a projection area of the magnetic member on the substrate covers an area disposed with the antenna.

2. The memory device of claim 1, wherein the semiconductor chip comprises a memory integrated circuit and a wireless recognition integrated circuit.

3. The memory device of claim 1, wherein the semiconductor package comprises a ground surface located on the substrate and an opposing active surface.

4. The memory device of claim 3, wherein the magnetic member is disposed on the active surface side.

5. The memory device of claim 1, wherein the magnetic member is disposed on an external surface of the semiconductor package.

6. The memory device of claim 5, wherein the semiconductor package comprises a ground surface facing toward the substrate and an opposing active surface, and the magnetic member is disposed on or at a position proximate to the active surface of the semiconductor package.

7. The memory device of claim 1, wherein the encapsulant further encapsulates the antenna.

8. The memory device of claim 1, wherein the semiconductor package further comprises a control chip.

9. A portable electronic apparatus, comprising:
a casing;
a circuit board disposed inside the casing; and
the memory device of claim 1 mounted on the circuit board.

10. The portable electronic apparatus of claim 9, wherein the semiconductor chip comprises a memory integrated circuit and a wireless recognition integrated circuit.

11. The portable electronic apparatus of claim 9, wherein the semiconductor package comprises a ground surface facing toward the substrate and an opposing active surface, and the magnetic member is disposed in the semiconductor package at a position proximate to the active surface side.

12. The portable electronic apparatus of claim 9, wherein the semiconductor package comprises a ground surface on the substrate and an opposing active surface, wherein the magnetic member is disposed on the active surface of the semiconductor package.

13. The portable electronic apparatus of claim 9, wherein the encapsulant further encapsulates the antenna.

14. The portable electronic apparatus of claim 9, wherein the semiconductor package further comprises a control chip.
